(19) United States
(12) Patent Application Publication
(10) Pub. No.: US 2025/0221219 A1
(43) Pub. Date: Jul. 3, 2025

(54) PIXEL ARRANGEMENT STRUCTURE, DISPLAY PANEL, AND DISPLAY DEVICE

(71) Applicant: Hubei Yangtze Industrial Innovation Center of Advanced Display Co., LTD., Wuhan (CN)

(72) Inventors: Shengxiong CHEN, Wuhan (CN); Yangzhao MA, Wuhan (CN); Qin YUE, Wuhan (CN); Wei HUANG, Wuhan (CN); Enxia WANG, Wuhan (CN)

(21) Appl. No.: 18/734,092

(22) Filed: Jun. 5, 2024

(30) Foreign Application Priority Data
Dec. 29, 2023 (CN) 202311870788.7

(51) Int. Cl. H10K 59/35

(52) U.S. Cl. CPC H10K 59/353; H10K 59/352

(57) ABSTRACT

A pixel arrangement structure, a display panel, and a display device are provided. The pixel arrangement structure includes first sub-pixels, second sub-pixels, and third sub-pixels. Two first sub-pixels arranged at opposite positions and two second sub-pixels arranged at opposite positions form a first virtual trapezoid, and centers of the two first sub-pixels and centers of the two second sub-pixels are respectively located on vertices of the first virtual trapezoid. One corresponding third sub-pixel is located inside the first virtual trapezoid. The third sub-pixel includes a first side and a second side respectively adjacent to the two first sub-pixels, and a third side and a fourth side respectively adjacent to the second sub-pixels. A length of the first side is not equal to a length of the second side, and/or, a length of the third side is not equal to a length of the fourth side.

### CROSS-REFERENCE TO RELATED APPLICATION

This application claims the priority of Chinese Patent Application No. 202311870788.7, filed on Dec. 29, 2023, the content of which is incorporated herein by reference in its entirety.

### TECHNICAL FIELD

The present disclosure generally relates to the field of display technology and, more particularly, relates to a pixel arrangement structure, a display panel, and a display device.

### BACKGROUND

Organic light-emitting diodes (OLED) have attracted widespread attention because of their characteristics of self-illumination, low power consumption, high brightness, and fast response. Organic self-luminous display technology has become the focus of current research in the display field.

To realize a full-color display of an OLED display panel, a plurality of sub-pixels with different light-emitting colors, such as red sub-pixels R, green sub-pixels G, and blue sub-pixels B, etc., is provided in the display panel. The arrangement of pixels in the display panel directly affects the display performance of the OLED display panel. How to arrange the various sub-pixels in the display panel to improve the performance of the display panel has become a research focus.

### SUMMARY

One aspect of the present disclosure provides a pixel arrangement structure. The pixel arrangement structure includes first sub-pixels, second sub-pixels, and third sub-pixels. Two first sub-pixels arranged at opposite positions and two second sub-pixels arranged at opposite positions form a first virtual trapezoid, and centers of the two first sub-pixels and centers of the two second sub-pixels are respectively located on vertices of the first virtual trapezoid. One corresponding third sub-pixel is located inside the first virtual trapezoid. The third sub-pixel includes a first side and a second side respectively adjacent to the two first sub-pixels, and a third side and a fourth side respectively adjacent to the second sub-pixels. A length of the first side is not equal to a length of the second side, and/or, a length of the third side is not equal to a length of the fourth side.

Another aspect of the present disclosure provides a display panel. The display panel includes a pixel arrangement structure. The pixel arrangement structure includes first sub-pixels, second sub-pixels, and third sub-pixels. Two first sub-pixels arranged at opposite positions and two second sub-pixels arranged at opposite positions form a first virtual trapezoid, and centers of the two first sub-pixels and centers of the two second sub-pixels are respectively located on vertices of the first virtual trapezoid. One corresponding third sub-pixel is located inside the first virtual trapezoid. The third sub-pixel includes a first side and a second side respectively adjacent to the two first sub-pixels, and a third side and a fourth side respectively adjacent to the second sub-pixels. A length of the first side is not equal to a length of the second side, and/or, a length of the third side is not equal to a length of the fourth side.

Another aspect of the present disclosure provides a display device. The display device includes a display panel. The display panel includes a pixel arrangement structure. The pixel arrangement structure includes first sub-pixels, second sub-pixels, and third sub-pixels. Two first sub-pixels arranged at opposite positions and two second sub-pixels arranged at opposite positions form a first virtual trapezoid, and centers of the two first sub-pixels and centers of the two second sub-pixels are respectively located on vertices of the first virtual trapezoid. One corresponding third sub-pixel is located inside the first virtual trapezoid. The third sub-pixel includes a first side and a second side respectively adjacent to the two first sub-pixels, and a third side and a fourth side respectively adjacent to the second sub-pixels. A length of the first side is not equal to a length of the second side, and/or, a length of the third side is not equal to a length of the fourth side.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a pixel arrangement structure;

FIG. 2 illustrates another pixel arrangement structure;

FIG. 3 illustrates an exemplary pixel arrangement structure consistent with various disclosed embodiments in the present disclosure;

FIG. 4 illustrates an exemplary pixel arrangement structure (not showing boundaries of evaporation openings) consistent with various disclosed embodiments in the present disclosure;

FIG. 5 illustrates a local structure of an exemplary pixel arrangement structure consistent with various disclosed embodiments in the present disclosure;

FIG. 6 illustrates a comparison between a third sub-pixel consistent with various disclosed embodiments in the present disclosure and a third sub-pixel in existing technologies;

FIG. 7 illustrates an exemplary third sub-pixel consistent with various disclosed embodiments in the present disclosure;

FIG. 8 illustrates another exemplary pixel arrangement structure consistent with various disclosed embodiments in the present disclosure;

FIG. 9 illustrates another exemplary pixel arrangement structure consistent with various disclosed embodiments in the present disclosure;

FIG. 10 illustrates another exemplary pixel arrangement structure consistent with various disclosed embodiments in the present disclosure;

FIG. 11 illustrates an exemplary display panel consistent with various disclosed embodiments in the present disclosure; and

FIG. 12 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, the term “and/or” is just an association relationship describing related objects, indicating that there may be three relationships. For example, A and/or B, may mean: A alone exists, A and B exist simultaneously, or B alone exists. Further, the character “/” in the present disclosure generally indicates that the related objects are an “or” relationship.

In the present disclosure, the term “electrical connection” may refer to a direct electrical connection between two components, or may refer to an electrical connection between two components via one or more other components. The term “drive” may mean “control” or “operate”. The term “part” may mean “partially”. The term “pattern” may refer to a “member”. The term “end” may refer to an “end segment” or an “end side”. The display panel may be a display device or a module/part of a display device.

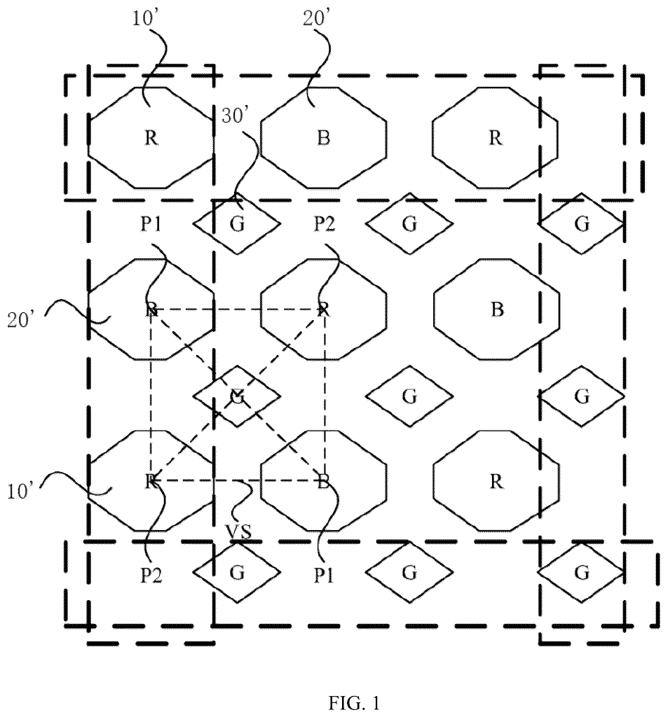

A diamond pixel arrangement structure has the advantages of clear text display, thin strokes, or relatively slight jaggedness, but also has some technical problems that need to be solved. Exemplarily, as shown in FIG. 1 which is a schematic diagram of a pixel arrangement structure in existing technologies, the pixel arrangement structure includes first sub-pixels 10′, second sub-pixels 20′, and third sub-pixels 30′. One third sub-pixel 30′ has a center coincident with a center of a corresponding virtual square VS. One second sub-pixel 20′ is spaced apart from one corresponding third sub-pixel 30′, and has a center at a first vertex Pl of one corresponding virtual square VS. One first sub-pixel 10′ is spaced apart from one corresponding second sub-pixel 20′ and one corresponding third sub-pixel 30′, and has a center at a second vertex P2 adjacent to the first vertex P1 of one corresponding virtual square VS. Since the angle between the two adjacent sides formed by the second sub-pixels 20′ and the third sub-pixel 30′ of this design is 90° and form a virtual square VS, which is similar in shape to a rhombus/diamond structure, it is usually called a diamond pixel arrangement.

The diamond pixel arrangement structure has a serious color fringing effect. The color fringing effect means that obvious color stripes that deviate from the original image appear on the side of the image when the display panel displays an image.

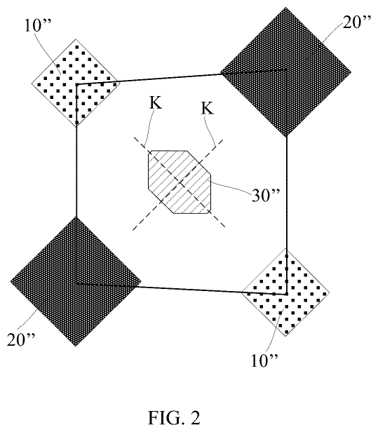

Another pixel arrangement structure improves the diamond pixel arrangement structure and aims to weaken the color fringing effect. FIG. 2 is a schematic diagram of another pixel arrangement structure in existing technologies. As shown in FIG. 2, lines connecting the centers of the first sub-pixels 10″ and the centers of the second sub-pixel 20″ form virtual trapezoids, and one third sub-pixel 30″ is located inside one corresponding virtual trapezoid. Therefore, the first sub-pixels 10″ or the second sub-pixels 20″ are offset, and a row (or a column) formed by the centers of multiple first sub-pixels 10″ and a row (or a column) formed by the centers of multiple second sub-pixels 20″′ are not on a same straight line, avoiding forming colored sides and weakening the color fringing effect. In this pixel arrangement structure, one third sub-pixel 30″ has two symmetry axes K. Since the lines connecting the centers of the first sub-pixels 10″ and the centers of the second sub-pixel 20″ form the virtual trapezoids, for the third sub-pixel 30″ with a shape with two symmetry axes, it is difficult to maximize the use of the space between the first sub-pixels and the second sub-pixels on the basis of meeting the minimum spacing requirements between sub-pixels, resulting in a lower aperture ratio of the third sub-pixel 30″. Therefore, the life of the light-emitting device corresponding to the third sub-pixels is affected.

The present disclosure provides a pixel arrangement structure, a display panel, and a display device, to at least partially alleviate the above problems. In the present disclosure, the pixel arrangement structure may include first sub-pixels, second sub-pixels, and third sub-pixels. Two first sub-pixels arranged at opposite positions and two second sub-pixels arranged at opposite positions may form a first virtual trapezoid. Centers of the two first sub-pixels and centers of the two second sub-pixels may be respectively located at vertices of the first virtual trapezoid, and one corresponding third sub-pixel may be located inside the first virtual trapezoid. The third sub-pixel may include a first side and a second side respectively adjacent to the two first sub-pixels, and a third side and a fourth side respectively adjacent to the two second sub-pixels. The length of the first side may be not equal to the length of the second side, and/or, the length of the third side may be not equal to the length of the fourth side.

In the present disclosure, the two first sub-pixels arranged at opposite positions and the two second sub-pixels arranged at opposite positions may form one first virtual trapezoid, that is, the first sub-pixels or the second sub-pixels may be offset. The offset of sub-pixels may weaken the color fringing effect. On the basis that the two first sub-pixels arranged at opposite positions and the two second sub-pixels arranged at opposite positions may form the first virtual trapezoid, the third sub-pixel may include the first side and the second side respectively adjacent to the two first sub-pixels, and the third side and the fourth side respectively adjacent to the two second sub-pixels. The length of the first side may be not equal to the length of the second side, and/or, the length of the third side may be not equal to the length of the fourth side. Therefore, the third sub-pixel may have at most one symmetry axis, or no symmetry axis at all. On the basis of meeting the minimum spacing requirements between sub-pixels, the third sub-pixel may occupy a larger space. The aperture ratio of the third sub-pixel may be thereby increased and the service life of a light-emitting device corresponding to the third sub-pixel may be improved.

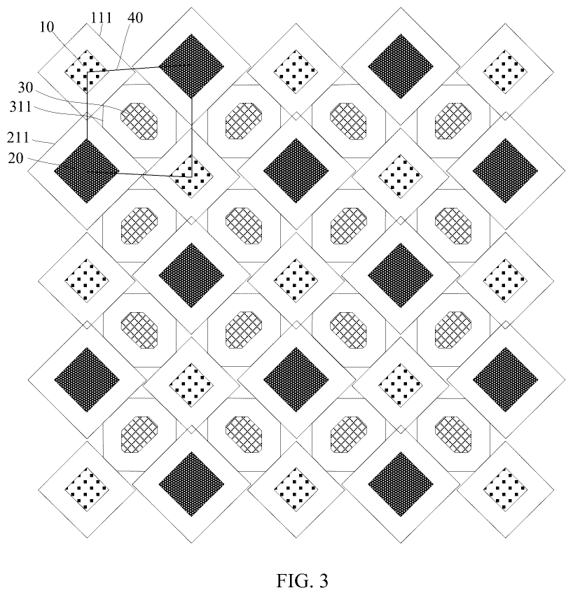

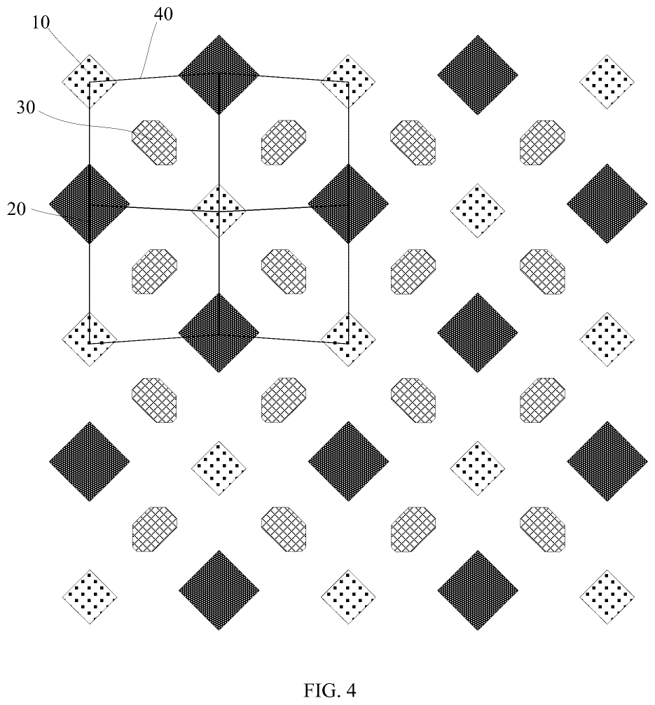

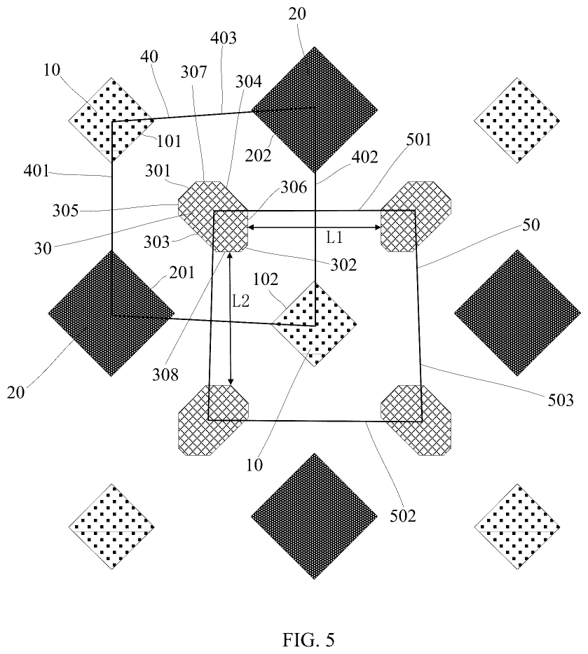

In one embodiment shown in FIG. 3 which illustrates an exemplary pixel arrangement structure, FIG. 4 which illustrates the pixel arrangement structure not showing the boundaries of evaporation openings, and FIG. 5 which illustrates a local structure of the exemplary pixel arrangement structure, the pixel arrangement structure may include first sub-pixels 10, second sub-pixels 20, and third sub-pixels 30. Two first sub-pixels 10 arranged at opposite positions and two second sub-pixels 20 arranged at opposite positions may form a first virtual trapezoid 40. Centers of the two first sub-pixels 10 and centers of the two second sub-pixels 20 may be respectively located at vertices of the first virtual trapezoid 40, and one corresponding third sub-pixel 30 may be located inside the first virtual trapezoid 40. The third sub-pixel 30 may include a first side 301 and a second side 302 respectively adjacent to the two first sub-pixels 10, and a third side 303 and a fourth side 304 respectively adjacent to the two second sub-pixels 20. A length of the first side 301 may not be equal to a length of the second side 302, and/or a length of the third side 303 may not be equal to a length of the fourth side 304.

In one embodiment, for example, the first sub-pixels 10 may be red sub-pixels, the second sub-pixels 20 may be blue sub-pixels, and the third sub-pixels 30 may be green sub-pixels. As shown in FIG. 3 and FIG. 4, the two first sub-pixels 10 arranged at opposite positions and the two second sub-pixels 20 arranged at opposite positions may form the first virtual trapezoid 40. Compared with the diamond pixel arrangement, at least one of the first sub-pixels 10 and the second sub-pixels 20 may be offset, and a row (or a column) formed by the centers of multiple first sub-pixels 10 and a row (or a column) formed by the centers of multiple second sub-pixels 20 may be not on a same straight line, such that the two cannot form a magenta color side, thus weakening the color fringing effect.

Further, the third sub-pixel 30 may include the first side 301 and the second side 302 respectively adjacent to the two first sub-pixels 10, and the third side 303 and the fourth side 304 respectively adjacent to the two second sub-pixels 20. The length of the first side 301 may not be equal to the length of the second side 302, and/or, the length of the third side 303 may not be equal to the length of the fourth side 304. When the length of the first side 301 may not be equal to the length of the second side 302, the third sub-pixel 30 may have at most one symmetry axis. When the length of the third side 303 may not be equal to the length of the fourth side 304, the third sub-pixel 30 may have at most one symmetry axis. When the length of the first side 301 may not be equal to the length of the second side 302 and the length of the third side 303 may not be equal to the length of the fourth side 304, the third sub-pixel 30 may not have any symmetry axis. Compared with the situation where the third sub-pixel 30″ has two symmetry axes in existing technologies, the position and length of each side of the third sub-pixel 30 may be configured more flexibly in the present disclosure, such that the third sub-pixel 30 may be able to fully utilize the space between the first sub-pixels 10 and the second sub-pixels 20. The aperture ratio of the third sub-pixel 30 may be increased, thereby increasing the service life of the light-emitting device corresponding to the third sub-pixel 30.

In FIG. 3, a line frame 111 on a periphery of one first sub-pixel 10 represents a boundary of an evaporation opening on a mask used for forming the first sub-pixel 10, a line frame 211 on a periphery of one second sub-pixel 20 represents a boundary of an evaporation opening on the mask used for forming the second sub-pixel 20, and a line frame 311 on a periphery of one third sub-pixel 30 represents a boundary of an evaporation opening on the mask used to form the third sub-pixel 30. Taking the first sub-pixels 10 as an example, the mask used to make the first sub-pixels 10 may be provided with evaporation openings. During evaporation, luminescent material of one first sub-pixel 10 may be formed in an area corresponding to one corresponding evaporation opening. Affected by the evaporation process, the area of the luminescent material may be smaller than the area of the corresponding evaporation opening. Therefore, there may be a certain distance between the boundary of the first sub-pixel 10 and the boundary of the corresponding evaporation opening. The shape of the sub-pixel depends on the shape of the corresponding evaporation opening, and each side of the sub-pixel may have a one-to-one correspondence with each side of the corresponding evaporation opening. Based on this, the size of any side of the sub-pixel should not be too small, otherwise the size of the corresponding side of the corresponding evaporation opening may be too small, resulting in a decrease in the processing accuracy of the evaporation opening. Further, when the size of the side of the sub-pixel is too small, a size of a corresponding side of a corresponding pixel opening in the display panel may be too small, increasing the difficulty of exposure. Also, because of the limitations of the photolithography process, the production accuracy of the corresponding pixel opening may also be reduced, resulting in problems of unclean etching and residue. In the embodiment of the present disclosure, the length of the first side 301 may not be equal to the length of the second side 302, and/or, the length of the third side 303 may not be equal to the length of the fourth side 304. The aperture ratio of the third sub-pixel 30 may be increased. Also, the size of each side of the third sub-pixel 30 and the size of each side of the corresponding evaporation opening on the mask may be ensured to not be too small. Therefore, the processing accuracy of the evaporation openings on the mask and the manufacturing accuracy of the pixel openings in the display panel may be ensured.

In one embodiment shown in FIG. 5 which is a local structure of a pixel arrangement structure, the first virtual trapezoid 40 may include a first short side 401, a first long side 402 and two first hypotenuses 403. The first short side 401 may be parallel to the first long side 402. The first side 301 may be adjacent to one first sub-pixel 10 located on the first short side 401, the second side 302 may be adjacent to one first sub-pixel 10 located on the first long side 402. The length of the first side 301 may be larger than the length of the second side 302.

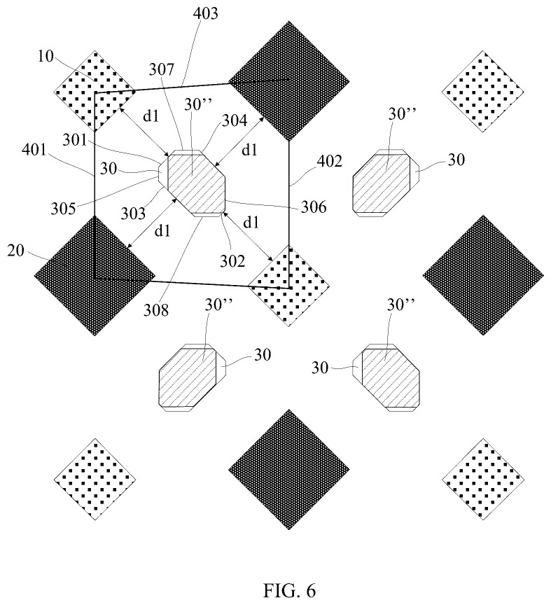

FIG. 6 is a schematic diagram comparing the third sub-pixel provided by the present disclosure and the third sub-pixel in existing technologies. As shown in FIG. 5 and FIG. 6, the length or position of each side of the third sub-pixel 30 in the embodiment of the present disclosure may be adjusted with respect to the length or position of each side of the third sub-pixel 30″ in existing technologies. Before and after the adjustment, the distance between the third sub-pixel 30 and the surrounding first sub-pixels 10 and the second sub-pixels 20 needs to be kept unchanged. That is to say, the distance from the third sub-pixel 30″ to the surrounding first sub-pixels 10 and second sub-pixels 20 is d1 before the adjustment, and the distance from the adjusted third sub-pixel 30 to the surrounding first sub-pixels 10 and second sub-pixels 20 may be still d1. Therefore, the specific adjustment manners may include changing the length of the sides adjacent to the first sub-pixels 10 and the second sub-pixels 20, or changing the position of the sides that are not adjacent to the first sub-pixels 10 and the second sub-pixels 20.

In one embodiment shown in FIG. 6, one way to adjust the third sub-pixel may include: extending one side adjacent to one of the first sub-pixels 10 in both directions to obtain the first side 301, extending one side adjacent to another first sub-pixel 10 in one direction to obtain the second side 302, extending one side adjacent to one of the second sub-pixels 20 in two directions to obtain the third side 303, and extending one side adjacent to another second sub-pixel 20 to obtain the fourth side 304. Compared with the third sub-pixel 30″ before adjustment, the third sub-pixel 30 obtained by the above adjustment method may increase the area without changing the distance from the surrounding first sub-pixels 10 and second sub-pixels 20. Therefore, on the basis of increasing the aperture ratio of the third sub-pixel 30, the evaporation opening corresponding to the third sub-pixel opening may be further increased.

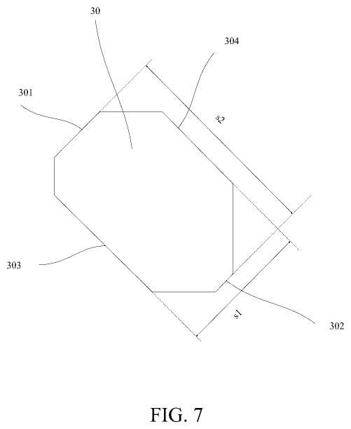

In the above adjustment method, the first side 301 may be obtained by bidirectional extension, and the second side 302 may be obtained by unidirectional extension. Therefore, the length of the first side 301 may be larger than the length of the second side 302. That is, making the length of the first side 301 larger than the length of the second side 302 may be a necessary condition for adopting the above adjustment method. Therefore, making the length of the first side 301 longer than the length of the second side 302 may be beneficial to improving the aperture ratio of the third sub-pixel 30. FIG. 7 is a schematic diagram of the third sub-pixel in one embodiment of the present disclosure. As shown in FIG. 7, in one embodiment, the ratio of the length of the first side 301 to the length of the second side may be larger than 1 and less than or equal to 15. When the ratio of the length of the first side 301 to the length of the second side 302 is larger than 1, the length of the first side 301 may be larger than the length of the second side 302, which is beneficial to improving the aperture ratio of the third sub-pixel 30. On the other hand, when the ratio of the length of the first side 301 to the length of the second side 302 is too large, the length of the second side 302 may be too small. From the above analysis, it can be seen that, when the length of the second side 302 is too small, the size of the corresponding side of the evaporation opening on the mask used to make the third sub-pixel 30 may be too small, and the size of the corresponding side of the pixel opening in the display panel may be too small, thus affecting the processing accuracy of the evaporation opening and pixel opening. Therefore, in this embodiment, the ratio of the length of the first side 301 to the length of the second side 302 may be limited to less than or equal to 15. Correspondingly, it may be ensured that the length of the second side 302 may not be too small, which is beneficial to ensuring the processing accuracy of the evaporation opening in the mask and pixel opening in the display panel.

In some embodiments, optimally the ratio of the length of the first side 301 to the length of the second side 302 may be set to larger than or equal to 2, and smaller than or equal to 4. Correspondingly, it may be further ensured that the length of the second side 302 may not be too small, which is beneficial to further ensuring the processing accuracy of the evaporation opening in the mask and pixel opening in the display panel. By setting the ratio of the length of the first side 301 to the length of the second side 302 to be larger than or equal to 2 and smaller than or equal to 4, while increasing the aperture ratio of the third sub-pixel 30, the processing accuracy of the evaporation opening in the mask and pixel opening in the display panel may be ensured.

In some embodiments, a vertical distance between the third side 303 and the fourth side 304 may be a first distance s1. A ratio of the length of the second side 302 to the first distance s1 may be larger than or equal to 1/10 and less than or equal to ⅓. By further limiting the ratio of the second side to the first distance s1, the length of the second side may be limited to a certain range. When the ratio is less than 1/10, it may mean that the length of the second side is shorter, which may increase the difficulty of exposure when forming pixel openings, reduce the etching accuracy, and also reduce the processing accuracy of the evaporation openings of the mask. When the ratio is larger than ⅓, the length of the first side 301 may be longer, which may reduce distances between the evaporation openings of the mask used by adjacent green sub-pixels and increase the difficulty of mask production. For details, please refer to L4 and L3 in FIG. 7 where L4 and L3 are the distances between evaporation openings of the mask for adjacent sub-pixels. When the length of the second side 302 is longer, L3 and L4 may be shortened, which increases difficulty of forming the mask. Therefore, limiting the length of the second side to the first distance s1 within a certain range may not only increase the aperture ratio, increase the life of the third sub-pixel, and improve the display effect during long-term display, but also reduce the production difficulty and the production cost of the mask.

In some embodiments, as shown in FIG. 5 and FIG. 6, the first virtual trapezoid 40 may include a first short side 401, a first long side 402 and two first hypotenuses 403. The first short side 401 and the first long side 402 may be parallel to each other. The third side 303 may be adjacent to the second sub-pixel 20 located on the first short side 401, the fourth side 304 may be adjacent to the second sub-pixel 20 located on the first long side 402, and the length of the third side 303 may be larger than the length of the fourth side 304.

In one embodiment, the third side 303 may be obtained by extension in two directions, and the fourth side 304 may be obtained by extension in one direction. Therefore, the length of the third side 303 may be larger than the length of the fourth side 304. That is, making the length of the third side 303 larger than the length of the fourth side 304 may be a necessary condition for adopting the above adjustment method. Therefore, making the length of the third side 303 larger than the length of the fourth side 304 may be beneficial to improving the aperture ratio of the third sub-pixel 30.

Further, the ratio of the length of the third side 303 to the length of the fourth side 304 may be larger than 1 and less than or equal to 5. When the ratio of the length of the third side 303 to the length of the fourth side 304 satisfies the above range, the aperture ratio of the third sub-pixel 30 may be increased. In addition, the length of the fourth side 304 may be prevented from being too small, thereby ensuring the processing accuracy of the evaporation openings in the mask used to make the third sub-pixel 30 and the manufacturing accuracy of the pixel openings in the display panel.

In one embodiment, preferably, the ratio of the length of the third side 303 to the length of the fourth side 304 may be larger than or equal to 1.2 and less than or equal to 1.6. This arrangement may further ensure that the length of the fourth side 304 is not too small, thereby further ensuring the processing accuracy of the evaporation openings of the mask used to make the third sub-pixel 30 and the manufacturing accuracy of the pixel openings.

In some embodiments, as shown in FIG. 7, the vertical distance between the first side 301 and the second side 302 may be a second distance s2, and the ratio of the length of the fourth side 304 to the second distance s2 may be larger than or equal to 1/2.5, and less than or equal to 1/1.5. Correspondingly, while ensuring a large pixel opening, the distance between evaporation openings in the mask for adjacent sub-pixels may also be maintained within a reasonable and processable range.

In some embodiments, as shown in FIG. 7, the vertical distance between the first side 301 and the second side 302 may be the second distance s2, and the vertical distance between the third side 303 and the fourth side 304 may be the first distance s1. The ratio between the first distance s1 and the second distance s2 may be larger than or equal to 1/1.8 and less than or equal to 1/1.5. By limiting the ratio between the first distance s1 and the second distance s2 to an appropriate range, on the basis of ensuring that the distance between the third sub-pixel and the adjacent first and second sub-pixels remains consistent, the aperture ratio of the sub-pixels may be increased.

In some embodiments shown in FIG. 5 and FIG. 6, the third sub-pixel 30 may also include a fifth side 305 and a sixth side 306. The fifth side 305 may be close to the first short side 401 and parallel to the first short side 401. The sixth side 306 may be close to the first long side 402 and parallel to the first long side 402. The length of the fifth side 305 may be smaller than the length of the sixth side 306.

In the aforementioned adjustment method, the first side 301 may be obtained by bidirectional extension, and the third side 303 may be obtained by extension in one direction. Therefore, the fifth side 305 after the adjustment may be translated in the direction toward the first short side 401. This translation may cause the fifth side 305 to become smaller in length. Therefore, configuring the third sub-pixel 30 such that the length of the fifth side 305 is smaller than the length of the sixth side 306 may be a necessary condition for adopting the above adjustment method. Therefore, making the length of the fifth side 305 smaller than the length of the sixth side 306 may be beneficial to improving the aperture ratio of the third sub-pixel 30.

Further, the ratio of the length of the sixth side 306 to the length of the fifth side 305 may be larger than 1 and less than or equal to 3. When the ratio of the length of the sixth side 306 to the length of the fifth side 305 satisfies the above range, the aperture ratio of the third sub-pixel 30 may be increased. Further, the length of the fifth side 305 may be prevented from being too small, thereby ensuring the processing accuracy of the evaporation openings in the mask used to make the third sub-pixel 30 and the manufacturing accuracy of the pixel openings in the display panel.

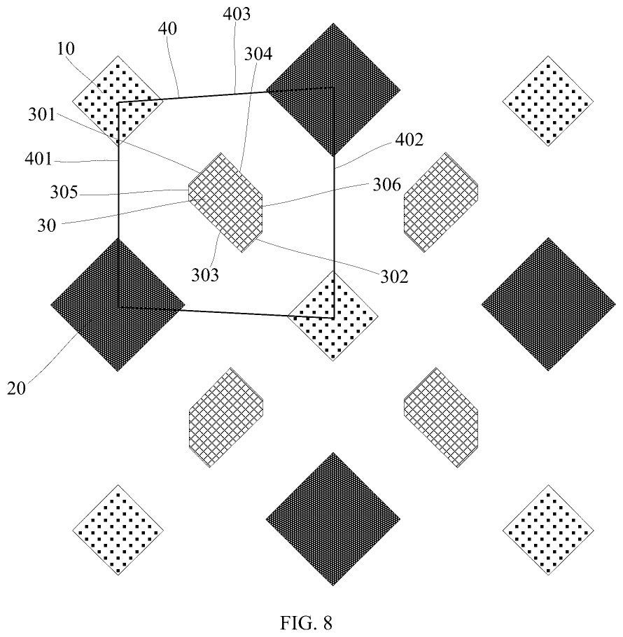

In one embodiment shown in FIG. 8 which is a schematic diagram of a pixel arrangement structure. the shapes of the first sub-pixels 10 and the second sub-pixels 20 may be a quadrilateral, and the shape of the third sub-pixel 30 may be a hexagon (as shown in FIG. 8) or octagon (shown in FIG. 5). Therefore, the space utilization of the third sub-pixel 30 may be increased, such that the third sub-pixel 30 may occupy as much space between the first sub-pixels 10 and the second sub-pixels 20 as possible. In some embodiments, when the shape of the third sub-pixel 30 is an octagon, the third sub-pixel 30 may also include a seventh side 307 and an eighth side 308. The seventh side 307 may be connected to the first side 301 and the fourth side 304 respectively. The eighth side 308 may be connected to the second side 302 and the third side 303 respectively.

As shown in FIG. 5, in one embodiment, the shapes of the first sub-pixels 10 and the second sub-pixels 20 may be a quadrilateral, and the shape of the third sub-pixel 30 may be an octagon. A minimum distance between two adjacent third sub-pixels 30 along the first direction may be L1, and a minimum distance between two adjacent third sub-pixels 30 along the second direction may be L2, where L1=L2. The first direction may be perpendicular to the first short side 401, and the second direction may be perpendicular to the first short side 401.

The minimum distance LI between two third sub-pixels 30 adjacent along the first direction may be understood as the distance between the two sides of the two third sub-pixels 30 adjacent along the first direction that are close to each other. Similarly, the minimum distance L2 between two third sub-pixels 30 adjacent along the second direction may be understood as the distance between the two sides of the two third sub-pixels 30 adjacent along the second direction that are close to each other. In one embodiment, L1=L2. This setting may be beneficial to improving the distribution uniformity of the third sub-pixels 30 in the display panel.

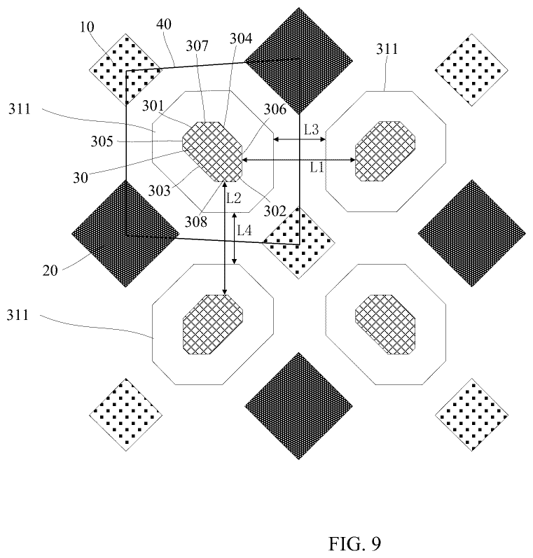

In one embodiment shown in FIG. 9 which is a schematic diagram of the pixel arrangement structure, as shown in FIG. 5 and FIG. 9, in the mask for forming the third sub-pixels 30, there may be a certain distance between the boundary of one evaporation opening and the boundary of one corresponding formed third sub-pixel 30, and because of the evaporation process, the distance from the boundary of each evaporation opening to the boundary of the corresponding third sub-pixel 30 may be equal. Therefore, when setting L1=L2, for the mask used to form the third sub-pixels 30, the distance L3 between two adjacent evaporation openings along the first direction may be the same as the distance LA between two adjacent evaporation openings in the second direction. Therefore, the distribution uniformity of the evaporation openings on the mask may be significantly improved, thereby improving the uniformity of the force on the mask when the mesh is stretched.

In the present disclosure, in the third sub-pixel 30, the length of the first side 301 may be not equal to the length of the second side 302, and/or, the length of the third side 303 may be not equal to the length of the fourth side 304. The shape of the third sub-pixel 30 may be an octagon, and the length of the fifth side 305 may be smaller than the length of the sixth side 306. Therefore, the positions of the fifth side 305, the sixth side 306, the seventh side 307, and the eighth side 308 may be adjusted more flexibly, thereby making it easier to realize the setting requirement of L1=L2. In the present disclosure, the third sub-pixel 30 may adopt an asymmetric shape, which may not only increase the aperture ratio of the third sub-pixel 30, but also help improve the uniform distribution of evaporation openings on the mask plate. The uniformity of the force on the mask when the mesh is stretched may be improved.

In some embodiments, as shown in FIG. 5, the first sub-pixel 10 located on the first short side 401 may have a first sub-side 101 adjacent to the third sub-pixel 30, and the first side 301 and the first sub-side 101 may be parallel to each other. The first sub-pixel 10 located on the first long side 402 may have a second sub-side 102 adjacent to the third sub-pixel 30, and the second side 302 may be parallel to the second sub-side 102. The second sub-pixel 20 located on the first short side 401 may have a third sub-side 201 adjacent to the third sub-pixel 30, and the third side 303 may be parallel to the third sub-side 201. The second sub-pixel 20 located on the first long side 402 may have a fourth sub-side 201 adjacent to the third sub-pixel 30, and the fourth side 304 may be parallel to the fourth sub-side 202.

The first side 301 of the third sub-pixel 30 may be parallel to the first sub-side 101, and the second side 302 of the third sub-pixel 30 may be parallel to the second sub-side 102. Therefore, the third sub-pixel 30 and the two first sub-pixels 10 may be complementary to each other in shape, which is beneficial to compact arrangement between the third sub-pixel 30 and the two first sub-pixels 10. Therefore, the area of the third sub-pixel 30 may be further increased, to further improve the aperture ratio of the third sub-pixel 30.

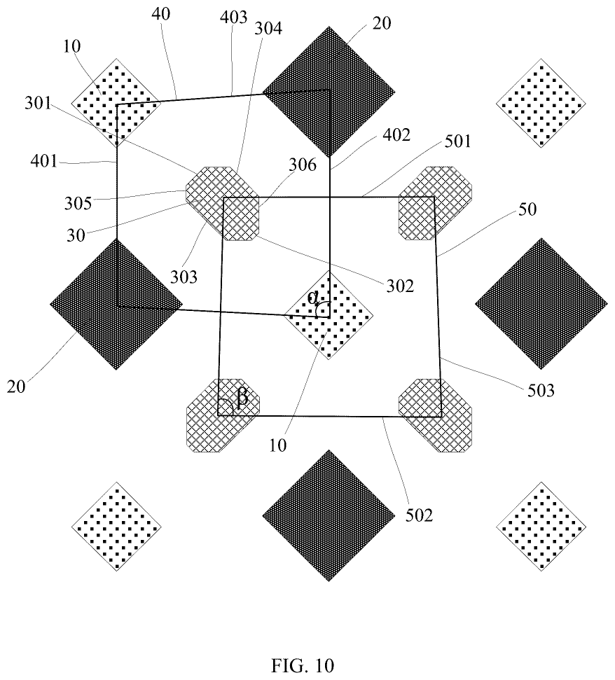

In one embodiment shown in FIG. 10 which is a schematic diagram of a pixel arrangement structure; as shown in FIG. 5 and FIG. 10, a plurality of third sub-pixels 30 may form a second virtual trapezoid 50. Centers of the third sub-pixels 30 may be located at the vertices of the second virtual trapezoid 50, and one corresponding first sub-pixel 10 may be located inside the second virtual trapezoid 50.

In one embodiment, the third sub-pixel 30 may be a green sub-pixel. The plurality of third sub-pixels 30 may form a second virtual trapezoid 50. Compared with the diamond pixel arrangement, at least one third sub-pixel 30 of the four third sub-pixels 30 may be offset, such that the number of the third sub-pixels 30 whose centers are located on one straight line may be reduced. The green color fringing may be weakened, thereby achieving the purpose of further weakening the color fringing effect.

In some embodiments, as shown in FIG. 10, the second virtual trapezoid 50 may include a second short side 501, a second long side 502 and two second hypotenuses 503. The second short side 501 may be parallel to the second long side 502. The first virtual trapezoid 40 and the second virtual trapezoid 50 may be both isosceles trapezoids. The first long side 402 and the first hypotenuse 403 may have a first included angle α, and the second long side 502 and the second hypotenuse 503 may have a second included angle β. The second included angle β may be larger than the first included angle α.

The second included angle β may be larger than the first included angle α. That is to say, the second virtual trapezoid 50 may be closer to a square than the first virtual trapezoid 40. In this way, on the one hand, the green color fringing may be weakened, and on the other hand, the green sub-pixels may have better distribution uniformity.

Further, in one embodiment, the first included angle a may be larger than or equal to 82° and less than or equal to 88°, and the second included angle β may be larger than or equal to 83° and less than or equal to 89°. The difference between the second included angle B and the first included angle a may be larger than or equal to 1° and less than or equal to 2°.

When the difference between the second included angle β and the first included angle α is too large, the uniformity and compactness of the arrangement of each sub-pixel may be reduced, which is not beneficial to improving the display effect and may affect the aperture ratio. Therefore, the difference between the second included angle β and the first included angle a may be set to be larger than or equal to 1° and less than or equal to 2°, thereby ensuring the uniformity and compactness of the sub-pixel arrangement and ensuring the display effect.

For example, in one embodiment, the first included angle α may be 87° and the second included angle β may be 88°. Therefore, on the basis of weakening the color fringing effect, the uniformity and compactness of the sub-pixel arrangement may be ensured, to improve the display effect.

In some embodiments, one first subpixel 10 may be one of a red subpixel and a blue subpixel, one second subpixel 20 may be another of a red subpixel and a blue subpixel, and one third subpixel 30 may be the green sub-pixel. When the first sub-pixel 10 is one of the red sub-pixel and the blue sub-pixel, and the second sub-pixel 20 is the other one of the red sub-pixel and the blue sub-pixel, the two first sub-pixels 10 arranged at opposite positions and two second sub-pixels 20 arranged at opposite positions may form the first virtual trapezoid 40, which may weaken the magenta color fringing.

In some embodiments, as shown in FIG. 3 and FIG. 4, the light-emitting area of the third sub-pixel 30 may be smaller than the light-emitting area of the first sub-pixel 10, and the light-emitting area of the third sub-pixel 30 may be smaller than the light-emitting area of the second sub-pixel 20. In the pixel arrangement structure in the embodiments of the present disclosure, the ratio of the numbers of the first sub-pixels 10, the number of the second sub-pixels 20, and the number of the third sub-pixels 30 may be 1:1:2. Therefore, each first sub-pixel 10 and each second sub-pixel 20 may be shared by two third sub-pixels 30. Since sharing, relatively fewer first sub-pixels 10 and second sub-pixels 20 may be able to achieve higher display resolution. The third sub-pixels 30 may be green sub-pixels, such that both the red sub-pixels and the blue sub-pixels may be shared by the green sub-pixels. That is, there may be no sharing phenomenon of green sub-pixels. Since human eyes are most sensitive to green, when the green sub-pixels are shared by other colors, the display panel may have obvious darkening. Therefore, setting the third sub-pixels 30 as the green sub-pixels may avoid the darkening of the display panel.

The present disclosure also provides a display panel 100. The display panel 100 may include any pixel arrangement structure provided by any embodiments of the present disclosure.

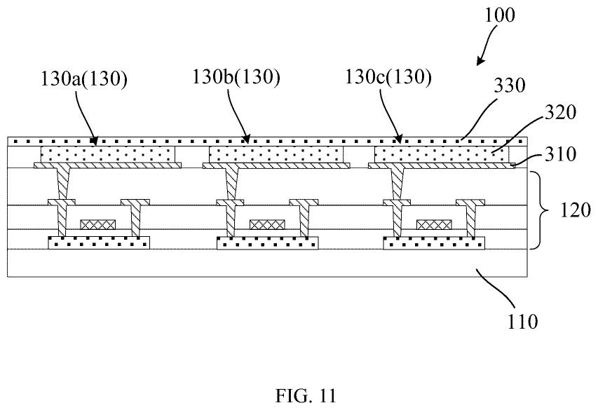

In one embodiment, the display panel 100 may be an OLED display panel. FIG. 11 is a schematic diagram of the display panel provided one embodiment of the present disclosure. As shown in FIG. 11, the display panel may further include a substrate 110, a driving circuit layer 120 disposed on one side of the substrate 110, and a display layer group disposed on a side of the driving circuit layer 120 facing away from the substrate. The display layer group may include a plurality of light-emitting elements 130. Specifically, the plurality of light-emitting elements 130 may include first light-emitting elements 130a for emitting light of a first color, second light-emitting elements 130b for emitting light of a second color, and third light-emitting elements 130c for emitting light of a third color. The first color, the second color and the third color may correspond to red, green and blue, for example.

One light-emitting element 130 may include a first electrode 310, a light-emitting body 320 disposed on a side of the first electrode 310 away from the driving circuit layer 120, and a second electrode 330 disposed on a side of the light-emitting body 320 away from the first electrode 310. The first electrode 310 may be an anode, and the second electrode 330 may be a cathode. Since the side where the cathode is located is usually the light-emitting side of the light-emitting element 300, the cathode may be a transparent electrode or a translucent electrode, and may be made of a material including, for example, ITO (indium tin oxide), IZO (indium zinc oxide), ITO/g/ITO, etc. The anode may be a metal electrode, and may be made of a material including, for example, Pt, Ru, Au, Ag, Mo, Al, W, etc. The light-emitting material of the light-emitting body 320 may be a or polymer organic material.

The display panel 100 may have the similar benefits as the pixel arrangement structure provided by various embodiments of the present disclosure.

The present disclosure also provides a display device 200. The display device 200 may include a display panel 100 provided by various embodiments of the present disclosure.

The display device 200 may have the similar benefits as the display panel provided by various embodiments of the present disclosure.

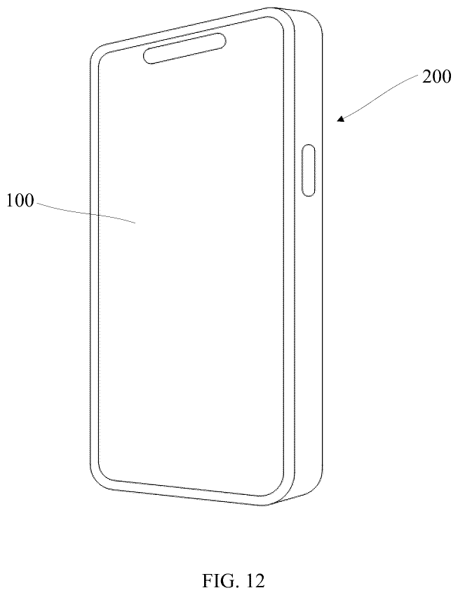

In one embodiment shown in FIG. 12, the display device may be a cell phone. In other embodiments, the display device may be, but is not limited to, TVs, laptops, desktop monitors, tablets, digital cameras, smart bracelets, smart glasses, vehicle monitors, industrial control equipment, medical displays, or touch interactive terminals, which is not limited in the present disclosure.

In this document, relational terms such as “first” and “second” are only used to distinguish one entity or operation from another entity or operation and do not necessarily require or imply that there is a relationship between these entities or operations. There is no such actual relationship or sequence. Furthermore, the terms “comprises,” “comprises,” or any other variations thereof are intended to cover a non-exclusive inclusion such that a process, method, article, or apparatus that includes a list of elements includes not only those elements, but also those not expressly listed other elements, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A pixel arrangement structure, comprising first sub-pixels, second sub-pixels, and third sub-pixels, wherein:
two first sub-pixels arranged at opposite positions and two second sub-pixels arranged at opposite positions form a first virtual trapezoid, wherein centers of the two first sub-pixels and centers of the two second sub-pixels are respectively located on vertices of the first virtual trapezoid, and one corresponding third sub-pixel is located inside the first virtual trapezoid;
the third sub-pixel includes a first side and a second side respectively adjacent to the two first sub-pixels, and a third side and a fourth side respectively adjacent to the second sub-pixels; and
a length of the first side is not equal to a length of the second side, and/or, a length of the third side is not equal to a length of the fourth side.

2. The pixel arrangement structure according to claim 1, wherein:
the first virtual trapezoid includes a first short side, a first long side and two first hypotenuses;
the first short side is parallel to the first long side;
the first side is adjacent to one first sub-pixel on the first short side;
the second side is adjacent to one first sub-pixel on the first long side; and
the length of the first side is larger than the length of the second side.

3. The pixel arrangement structure according to claim 2, wherein:
a ratio of the length of the first side to the length of the second side is larger than 1 and less than or equal to 15.

4. The pixel arrangement structure according to claim 3, wherein:
a vertical distance between the third side and the fourth side is a first distance, and a ratio of the length of the second side to the first distance is larger than or equal to 1/10 and less than or equal to ⅓.

5. The pixel arrangement structure according to claim 1, wherein:
the first virtual trapezoid includes a first short side, a first long side and two first hypotenuses;
the first short side is parallel to the first long side;
the third side is adjacent to one second sub-pixel located on the first short side;
the fourth side is adjacent to one second sub-pixel on the first long side; and
the length of the third side is longer than the length of the fourth side.

6. The pixel arrangement structure according to claim 5, wherein:
a ratio of the length of the third side to the length of the fourth side is larger than 1 and less than or equal to 5.

7. The pixel arrangement structure according to claim 6, wherein:
a vertical distance between the first side and the second side is a second distance, and a ratio of the length of the fourth side to the second distance is larger than or equal to 1/2.5 and less than or equal to 1/1.5.

8. The pixel arrangement structure according to claim 1, wherein:
a vertical distance between the first side and the second side is a second distance;
a vertical distance between the third side and the fourth side is a first distance; and
a ratio of the first distance to the second distance is larger than or equal to 1/1.8, and smaller than or equal to 1/1.5.

9. The pixel arrangement structure according to claim 2, wherein:
the third sub-pixel further includes a fifth side and a sixth side;
the fifth side is close to the first short side and parallel to the first short side;
the sixth side is close to the first long side and parallel to the first long side; and
a length of the fifth side is smaller than a length of the sixth side.

10. The pixel arrangement structure according to claim 9, wherein:
a ratio of the length of the sixth side to the length of the fifth side is larger than 1 and smaller than or equal to 3.

11. The pixel arrangement structure according to claim 9, wherein:
shapes of the first sub-pixels and the second sub-pixels are quadrilaterals, and a shape of the third sub-pixel is a hexagon.

12. The pixel arrangement structure according to claim 9, wherein:
shapes of the first sub-pixels and the second sub-pixels are quadrilaterals, and a shape of the third sub-pixel is an octagon;
the third sub-pixel further includes a seventh side and an eighth side, wherein the seventh side is connected to the first side and the fourth side respectively, and the eighth side is connected to the second side and the third side respectively.

13. The pixel arrangement structure according to claim 12, wherein:
a minimum distance between two third sub-pixels adjacent along a first direction is L1, and a minimum distance between two third sub-pixels adjacent along a second direction is L2, wherein L1=L2, the first direction is perpendicular to the first short side, and the second direction is parallel to the first short side.

14. The pixel arrangement structure according to claim 2, wherein:
one first sub-pixel located on the first short side has a first sub-side adjacent to the third sub-pixel, wherein the first side is parallel to the first sub-side;
one first sub-pixel located on the first long side has a second sub-side adjacent to the third sub-pixel, wherein the second side is parallel to the second sub-side;
one second sub-pixel located on the first short side has a third sub-side adjacent to the third sub-pixel, wherein the third side is parallel to the third sub-side; and
one second sub-pixel located on the first long side has a fourth sub-side adjacent to the third sub-pixel, wherein the fourth side is parallel to the fourth sub-side.

15. The pixel arrangement structure according to claim 2, wherein:
a plurality of third sub-pixels form a second virtual trapezoid, wherein centers of the plurality of third sub-pixels are located at vertices of the second virtual trapezoid and one corresponding first sub-pixel is located inside the second virtual trapezoid.

16. The pixel arrangement structure according to claim 15, wherein:
the second virtual trapezoid includes a second short side, a second long side and two second hypotenuses;
the second short side is parallel to the second long side;
the first virtual trapezoid and the second virtual trapezoid are both isosceles trapezoids; and
the first long side and the first hypotenuse have a first included angle, and the second long side and the second hypotenuse have a second included angle, wherein the second included angle is larger than the first included angle.

17. The pixel arrangement structure according to claim 16, wherein:
the first included angle is larger than or equal to 82° and less than or equal to 88°, and the second included angle is larger than or equal to 83° and less than or equal to 89°; wherein, the second included angle is larger than or equal to the first included angle; and
difference between the first included angle and the second included angle is larger than or equal to 1° and less than or equal to 2°.

18. The pixel arrangement structure according to claim 1, wherein:
a light-emitting area of one third sub-pixel is smaller than a light-emitting area of one first sub-pixel, and the light-emitting area of the third sub-pixel is smaller than a light-emitting area of one second sub-pixel.

19. A display panel, comprising a pixel arrangement structure, wherein:
the pixel arrangement structure includes first sub-pixels, second sub-pixels, and third sub-pixels:
two first sub-pixels arranged at opposite positions and two second sub-pixels arranged at opposite positions form a first virtual trapezoid, wherein centers of the two first sub-pixels and centers of the two second sub-pixels are respectively located on vertices of the first virtual trapezoid, and one corresponding third sub-pixel is located inside the first virtual trapezoid;
the third sub-pixel includes a first side and a second side respectively adjacent to the two first sub-pixels, and a third side and a fourth side respectively adjacent to the second sub-pixels; and
a length of the first side is not equal to a length of the second side, and/or, a length of the third side is not equal to a length of the fourth side.

20. A display device, comprising a display panel, wherein:
the display panel includes a pixel arrangement structure:
the pixel arrangement structure includes first sub-pixels, second sub-pixels, and third sub-pixels:
two first sub-pixels arranged at opposite positions and two second sub-pixels arranged at opposite positions form a first virtual trapezoid, wherein centers of the two first sub-pixels and centers of the two second sub-pixels are respectively located on vertices of the first virtual trapezoid, and one corresponding third sub-pixel is located inside the first virtual trapezoid;
the third sub-pixel includes a first side and a second side respectively adjacent to the two first sub-pixels, and a third side and a fourth side respectively adjacent to the second sub-pixels; and
a length of the first side is not equal to a length of the second side, and/or, a length of the third side is not equal to a length of the fourth side.
